(19) United States
(12) Patent Application Publication
(10) Pub. No.: US 2011/0210453 A1
(43) Pub. Date: Sep. 1, 2011

(54) METHOD FOR DESIGNING ELECTRONIC SYSTEM

(75) Inventors: Keiichi KUSUMOTO, Hyogo (JP); Shinya Tokunaga, Kyoto (JP); Mitumi Ito, Kyoto (JP); Koichi Seko, Osaka (JP)

(73) Assignee: Panasonic Corporation, Osaka (JP)

(21) Appl. No.: 13/107,269

(22) Filed: May 13, 2011

Related U.S. Application Data
(63) Continuation of application No. PCT/JP2009/005454, filed on Oct. 19, 2009.

(30) Foreign Application Priority Data
Dec. 11, 2008 (JP) 2008-316261

(51) Int. Cl. H01L 23/48; G06F 17/50

(52) U.S. Cl. 257/782; 716/137; 257/E23.01

(57) ABSTRACT

When an electronic system is designed, then if an integrated circuit chip (LSI), a package (PKG), and a printed circuit board (PCB) are designed separately and in parallel, it will be found near the end of the design process that a satisfactory electrical characteristic is not achieved. Therefore, a design procedure of each part (e.g., an LSI, a PKG, a PCB, etc.) is decided, and allocation of resources to a part which is designed with a higher priority is decided, and thereafter, the other parts start to be designed. Therefore, a basic interconnect distribution for a circuit board is calculated based on a prediction function for predicting an interconnect distribution for the circuit board using design information of the circuit board as input data, and is output.

### CROSS-REFERENCE TO RELATED APPLICATIONS

This is a continuation of PCT International Application PCT/JP2009/005454 filed on Oct. 19, 2009, which claims priority to Japanese Patent Application No. 2008-316261 filed on Dec. 11, 2008. The disclosures of these applications including the specifications, the drawings, and the claims are hereby incorporated by reference in their entirety.

### BACKGROUND

The present disclosure relates to methods for designing electronic systems, and more particularly, to technologies for design tools for reducing design time.

Electronic systems generally include various parts. Examples of the parts include discrete electronic parts, such as transistors, resistors, capacitors, inductors, etc., integrated circuit chips (large scale integration (LSI)), packages (PKGs) on which LSIs are mounted, and printed circuit boards (PCBs) for interconnecting PKGs.

Conventionally, parts constituting electronic systems are designed and manufactured by different companies. In particular, LSIs, PKGs, and PCBs are designed, assuming dedicated use by different electronic systems, and therefore, it takes about five or six months to design them. By simultaneously designing these parts in association with each other, the total design time may be reduced.

There is a known design technique relating to a tool for reducing the total design time by designing a PCB with a higher priority while simultaneously designing parts (see Japanese Patent Publication No. 2008-009776).

### SUMMARY

Near the end of the design process for all parts, a mismatch frequently occurs in interconnection of an LSI, a PKG, or a PCB. In this case, it is difficult to achieve the integrity of connection. Therefore, interconnects may need to be laid along a much longer path, or in the worst case, the connection may not be completed. In these situations, correction has to be made, e.g., the locations of input/output terminals of the LSI has to be changed, or the design process of the PKG has to be started over. As a result, interconnects may cross each other, or a power supply plane or a ground plane may not be provided, so that an electrical characteristic is degraded.

However, it is often in the final stage of the design process that it becomes clear that it is difficult to connect interconnects to parts. This imposes a significant limitation on the correction. Due to this limitation, current design technologies may fail to provide a satisfactory electrical characteristic etc. of interconnects with a sufficient margin. As a result, for example, the design process may be performed again from the initial stage. Therefore, unfortunately, the number of design steps may unavoidably be significantly increased, or the completion of the design process may have to be postponed.

In the future, electronic systems may have more complicated configurations. Specifically, many parts, such as LSIs and passive elements, may be mounted in a smaller volume. Therefore, the parts may be interconnected by using a complicated combination of wires, micrsosubstrates, silicon interposers, carbon nanotubes, etc. in addition to PCBs. Moreover, three-dimensional packaging may be developed, which allows a number of LSIs to be stacked.

Future electronic systems may have more complicated configurations than current ones, and designers may encounter more serious problems with the conventional art. Therefore, for example, it is difficult for a designer to intervene in designing an electronic system to decide a design plan based on experience, or it is difficult to select one which is designed with a higher priority from a plurality of parts for an electronic system. Therefore, it is considered that it will be impossible to optimize future electronic systems using the current electronic system design technologies.

According to the present disclosure, attention is paid to the circumstances that the speed of signals propagating through interconnects which connect together an LSI, a PKG, and a PCB included in an electronic system has been rapidly increased. Specifically, interconnects need not only to physically connect the input/output terminals of parts together, but also have an excellent electrical characteristic in order to propagate signals at high speed. The main purpose of conventional design technologies is to connect parts together using interconnects. As an electronic system is optimized in order to provide a satisfactory electrical characteristic which allows higher-speed signal propagation while ensuring the connection of the interconnects, the complexity of an evaluation index for optimization of design increases.

An influence of interconnect inductance will be described in detail with reference to FIG. 1. The horizontal axis indicates the rise times tr of a signal propagating through interconnects (a time required for the amplitude of the signal is changed from 10% to 90%), and the vertical axis indicates the lengths L of interconnects. Triangular regions (a), (b), and (c) for a PCB, a PKG, and an LSI indicate that inductance needs to be considered in the design process in order to obtain a satisfactory electrical characteristic. In the PCB region (a), when the rise time tr=0.1 ns and the interconnect length L=10-100 mm (zone L2), inductance needs to be considered in the design process, and when the interconnect length L=0-10 mm (zone L1), it can be said that there is almost no adverse influence of inductance on signal propagation. When the interconnect length L exceeds 100 mm, such an excessively long interconnect length causes a resistive characteristic, and therefore, it is not necessary to consider the influence of inductance. In this case, however, a longer propagation time is needed, and therefore, such a long interconnect cannot be used for high-speed signal propagation.

In conventional designs, the rise time tr of signals is 1 ns or more (corresponding to a frequency of about 200 MHz). Therefore, according to FIG. 1, none of LSIs, PKGs, and PCBs requires consideration of inductance in the design process, and the parts are designed with emphasis only on the connection of interconnects, but not on an electrical characteristic. On the other hand, as the speed of signal propagation has been rapidly increased in recent electronic systems, the rise time tr is approaching 0.1 ns (corresponding to a frequency of more than 1 GHz), and is expected to further decrease in the future. To achieve such high-speed signal propagation (e.g., the rise time tr is 0.01 ns), inductance needs to be considered in the design process for interconnection in the case of all LSIs, PKGs, and PCBs. Thus, it is increasingly important to design the interconnection of parts in consideration of an electrical characteristic of interconnects both now and in the future.

In such background, if an LSI, a PKG, and a PCB are designed separately and in parallel as in the conventional art, it will be found near the end of the design process that a satisfactory electrical characteristic is not achieved. Therefore, it is effective to decide a design procedure of each part (e.g., an LSI, a PKG, a PCB, etc.) while assigning a higher priority to a predetermined part in terms of designing of interconnection to efficiently allocate resources, before the start of the design process, i.e., to perform a preprocess before the start of designing the entire electronic system.

An example method for designing an electronic system according to the present disclosure includes the steps of calculating a basic interconnect distribution for a first circuit board based on a prediction function configured to predict an interconnect distribution for a circuit board using design information for the first circuit board as input data, and outputting the basic interconnect distribution. As a result, the basic interconnect distribution of the first circuit board can be estimated to decide a design plan for interconnection of the first circuit board before actually designing the electronic system.

Another example method for designing an electronic system according to the present disclosure includes the steps of calculating element interconnection resources within a structural limit of a first circuit board using, as input information, an interconnect distribution for the first circuit board and a structural limit of interconnects based on an electrical characteristic, and outputting the element interconnection resources. As a result, the element interconnection resources which provide a satisfactory level of the electrical characteristic is estimated from the basic interconnect distribution of the first circuit board to decide a design plan for interconnection of the first circuit board before actually designing the electronic system.

Another example method for designing an electronic system according to the present disclosure includes the steps of calculating a basic interconnect distribution for a first circuit board based on a prediction function configured to predict an interconnect distribution for a circuit board using design information for the first circuit board as first input data, calculating, as element interconnection resources, the basic interconnect distribution within a structural limit based on an electrical characteristic, and outputting a result of comparing the element interconnection resources with the number of requests for a signal requiring the electrical characteristic. As a result, a design plan for interconnection of the first circuit board including an electronic characteristic can be decided before actually designing the electronic system.

Another example method for designing an electronic system according to the present disclosure includes the steps of calculating a first interconnect distribution for a first circuit board based on a prediction function configured to predict an interconnect distribution for a circuit board using design information for the first circuit board as first input data, calculating, as first element interconnect resources, the basic interconnect distribution within a structural limit based on an electrical characteristic, and outputting a first result of comparing the element interconnection resources with the number of requests for a signal requiring the electrical characteristics, calculating a second interconnect distribution for a second circuit board based on a prediction function configured to predict an interconnect distribution for a circuit board using design information for the second circuit board as second input data, calculating, as second element interconnect resources, the basic interconnect distribution within a structural limit based on an electrical characteristic, and outputting a second result of comparing the element interconnection resources with the number of requests for a signal requiring the electrical characteristics, and outputting an analysis result of comparing the first comparison result with the second comparison result. As a result, it is possible to determine to which of the first and second circuit boards a higher priority is assigned in terms of designing of interconnection, in a design plan for interconnection of the first and second circuit boards including an electronic characteristic, before actually designing the electronic system.

According to the present disclosure, it is possible to provide a tool for deciding priority levels of designing of interconnection for LSIs, PKGs, and PCBs in a design process for an electronic system. By performing the design process based on the interconnect design priority levels thus decided, it is possible to reduce or avoid a situation that it will become clear in the final stage of the design process that it is difficult to connect interconnects to the parts, and therefore, interconnects need to be laid along a much longer path, or the design process needs to be started over, while providing a satisfactory electrical characteristic in the design of interconnects in an electronic system.

### BRIEF DESCRIPTION OF THE DRAWINGS

FIG. 1 is a diagram showing regions in which inductance need to be taken into consideration, with respect to signal transition times.

FIG. 2 is a diagram showing an electronic system having interconnects provided on a PCB.

FIG. 3 is a diagram showing a configuration according to a first embodiment of the present disclosure.

FIG. 4 is a diagram showing a distribution of interconnect lengths.

FIG. 5 is a diagram showing a configuration according to a second embodiment of the present disclosure.

FIG. 6 is a diagram showing a configuration according to a third embodiment of the present disclosure.

### DETAILED DESCRIPTION

Embodiments of the present disclosure will be described hereinafter with reference to the accompanying drawings.

### First Embodiment

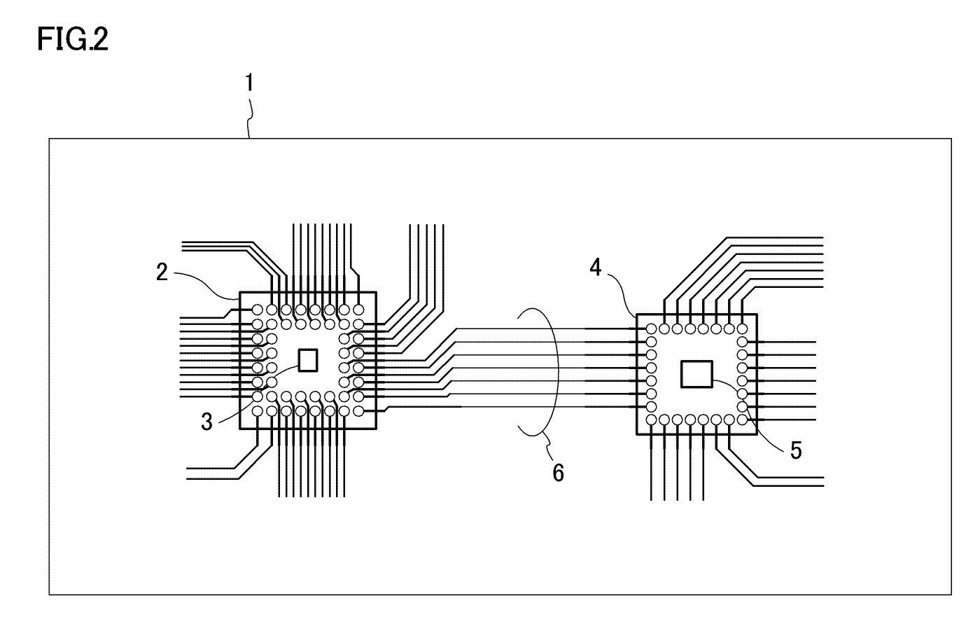

FIG. 2 shows an electronic system to be designed. In the electronic system of FIG. 2, parts, i.e., LSIs 3 and 5, PKGs 2 and 4, and a PCB 1 are electrically connected to each other via interconnects possessed by the parts and connectors which connect the interconnects together. As described above, it is important to analyze to which of the LSIs 3 and 5, the PKGs 2 and 4, and the PCB 1a higher priority should be assigned in terms of designing of interconnection, in order to obtain a most satisfactory interconnection design of the entire electronic system. In a first embodiment, a technique of estimating the relationship between the lengths and numbers of interconnects in interconnect resources possessed by the LSIs 3 and 5, the PKGs 2 and 4, and the PCB 1 included in the electronic system, to decide an optimum design procedure, will be described.

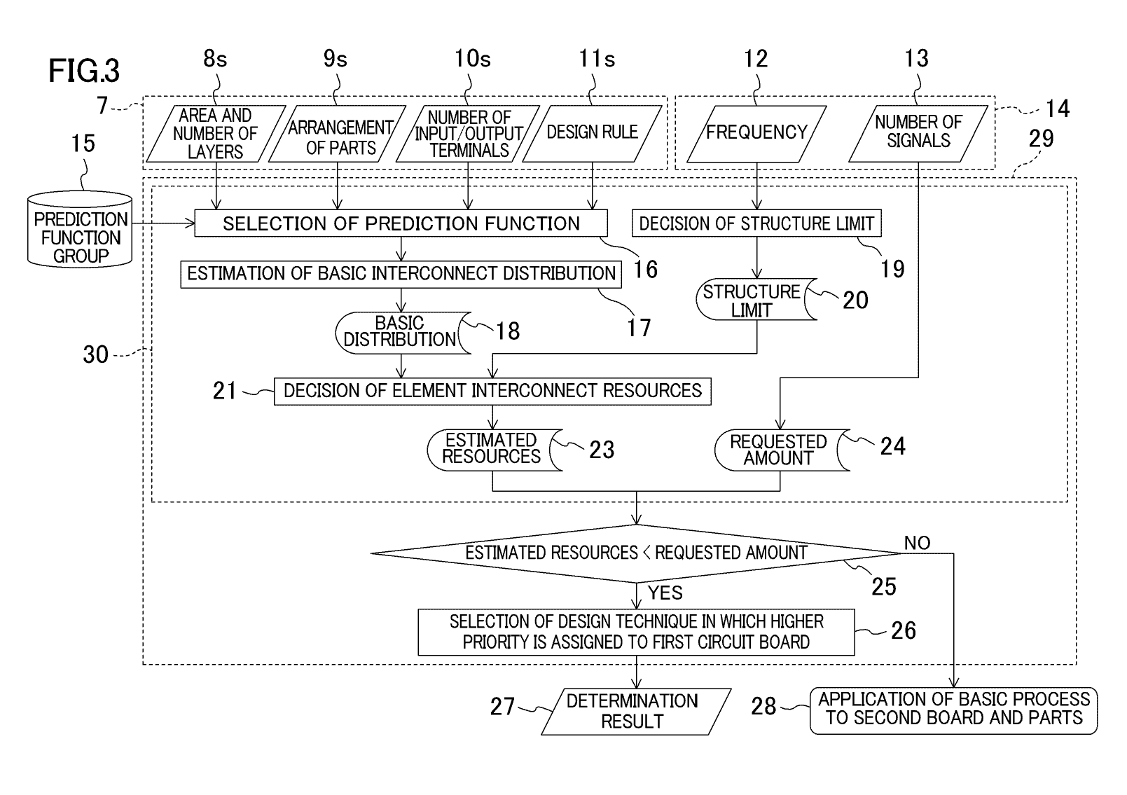

FIG. 3 is a diagram showing a technique of analyzing whether or not it is appropriate to assign a higher priority to designing of interconnection of the PCB 1 than those of the other parts. In the description which follows, the PCB 1 is generalized as a first circuit board. Board information 7 contains the area and the number of interconnection layers of the first circuit board (8s), the arrangement of parts on the first circuit board (9s), the number of input/output terminals of the first circuit board (10s), and the design rule of the first circuit board (11s). Based on the circuit board information 7, a resource calculation process 30 is performed to estimate interconnection resources for the first circuit board, which are referred to as a basic distribution 18. In element interconnection resource decision 21 within the limit of the first circuit board, the basic distribution 18 is divided into interconnection resources which do not require consideration of an electrical characteristic and interconnection resources which require consideration of an electrical characteristic. In prediction function selection 16, the basic distribution 18 which is a basic interconnect distribution of the first circuit board is estimated based on the circuit board information 7.

Here, the prediction function selection 16 will be described. In the electronic system of FIG. 2, the LSI 3 is provided on the PKG 2 with the LSI 3 being bonded face down to the PKG 2 using bumps. The LSI 5 is provided on the PKG 4 with the LSI 5 being bonded face down to the PKG 4 using bumps. The PKGs 2 and 4 are provided on the PCB 1 with the PKGs 2 and 4 being connected together via interconnects 6 of the PCB 1.

A prediction function group 15 is a group of functions decided by, for example, the following technique. Specifically, the lengths and numbers of interconnects of a PCB for each of some electronic systems which have already been designed and have configurations similar to that of an electronic system to be designed, are investigated. Based on the result of the investigation, the relationship between the length and number of interconnects can be formulated as:

N=F(L) (1)

where L is the length of interconnects, N is the number of the interconnects having the length L, and F is a function representing the relationship between the interconnect length L and the interconnect number N which is common to the existing electronic systems having configurations similar to that of the electronic system to be designed. The function F is estimated from the existing electronic systems and may be derived by using various techniques. One of the simplest techniques is to investigate the length and number of interconnects of a PCB in an existing electronic system, and represent the relationship between the length and number of interconnects as the function F. If there are a plurality of existing electronic systems, functions F1 and F2 may be calculated for the existing electronic systems before being merged into a function F3 by, for example, calculating an average of the functions F1 and F2. The derived functions are stored as Fi (i=0, 1, 2, 3, . . . , k, . . . , and n) in the prediction function group 15.

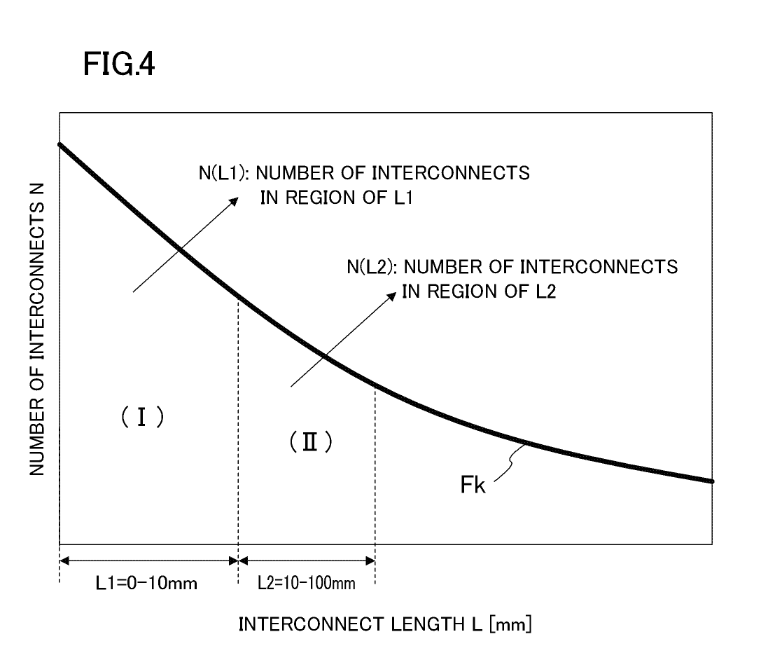

In the prediction function F selection 16, based on the circuit board information 7, one of the functions Fi (i=0, 1, 2, 3, . . . , k, . . . , and n) is decided to correspond to the first circuit board. Here, it is assumed that the function Fk is selected in the prediction function selection 16. In estimation 17 of a basic interconnect distribution based on a prediction function for the first circuit board, it can be estimated from expression (1) based on the function Fk that there are N (=Fk(L)) interconnects having the length L on the first circuit board to be designed, i.e., the basic interconnect distribution of the first circuit board can be estimated. Based on the function Fk, the basic interconnect distribution estimation 17 is performed based on the prediction function for the first circuit board to determine the basic distribution 18. The basic distribution 18 indicates one information form of the basic interconnect distribution. FIG. 4 shows the relationship N=Fk(L) between the interconnect length L and the interconnect number N.

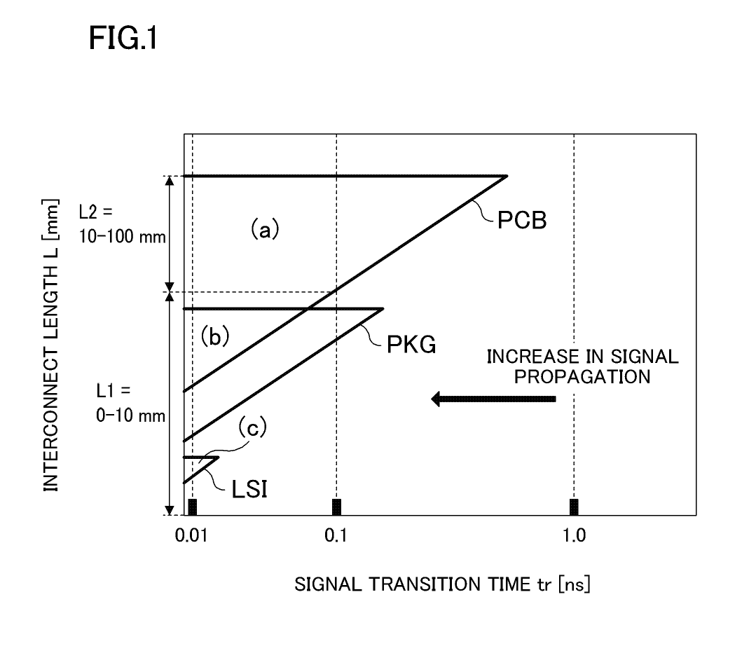

In interconnect structural limit decision 19, it is determined whether or not it is necessary to consider an electrical characteristic when signals propagate through interconnects. Input information is a signal frequency 12. As a specific technique, for example, the determination is performed based on an electrical circuit model. In FIG. 4, the horizontal axis indicates the interconnect length L, and the vertical axis indicates the interconnect number N. Of the interconnects of the PCB of FIG. 1, the number of interconnects in the interconnect region L1 where inductance does not need to be considered corresponds to the area of a region (I) in FIG. 4, i.e., N(L1). Similarly, the number of interconnects in the interconnect region L2 corresponds to the area of a region (II), i.e., N(L2). The numbers N(L1) and N(L2) (estimated resources 23) estimated based on the prediction function Fk are compared with the number (No) 13 of high-speed signals of interest (requested amount 24) which satisfy the frequency 12 required for the electronic system to be designed, in determination 25. In the determination 25, N(L1) of the estimated resources 23 is compared with No of the requested amount 24. When N(L1)<No, the requested amount 24 is larger than the estimated resources 23, indicating that, on the first circuit board, there is a lack of interconnects which provide a satisfactory electrical characteristic. Therefore, in selection 26, a design technique in which a higher priority is assigned to the first circuit board is selected. Here, in a first circuit board design priority determination result 27, the relationship between the estimated resources 23 and the requested amount 24 for the PCB 1 is indicated as output information. Thus, it can be seen that a higher priority is assigned to designing of interconnection for the first circuit board in the design process for the entire electronic system. On the other hand, when the estimated resources 23 are larger than the requested amount 24, the first circuit board has a sufficient number of interconnects which provide a satisfactory electrical characteristic. In this case, a basic process 29 is applied to a second circuit board or other parts (application 28). As in the case of the first circuit board, it can be determined whether or not it is necessary to assign a higher priority to designing of interconnection for the second circuit board than those of the other parts. Note that the following determination technique may be used.

(I) Case where No<N(L1)

The first circuit board has a sufficient number of interconnects which falls within an inductance design limit, and therefore, the required interconnect number No allows the design process to be performed without consideration of inductance. In this case, a design technique in which a higher priority is assigned to for another part is selected.

(II) Case where N(L1)<No<N(L2)

The first circuit board has N(L1) interconnects which fall within the inductance design limit and can be designed without consideration of inductance, and No−N(L1) interconnects which can be designed in consideration of inductance. In this case, a design method in which a higher priority is assigned to the first circuit board is selected.

(III) Case where N(L2)<No

The first circuit board has N(L2) interconnects which fall within the inductance design limit, and No−N(L2) interconnects which do not fall within the inductance design limit. In this case, the design of the first circuit board needs to be modified.

The basic process 29 is applied to each of the LSIs 3 and 5, the PKGs 2 and 4, and the PCB 1, where the estimated resources 23 are compared with the requested amount 24. If it is decided that a design technique in which a higher priority is assigned to the PCB 1 is needed, then when the interconnects 6 which need to provide a satisfactory electrical characteristic of the PCB 1 are designed with a higher priority, as shown in FIG. 2 interconnects from the LSI 3 to the PKG 2, interconnects from the PCB 1 to the PKG 4, and interconnects from the PKG 4 to the LSI 5 can be provided without crossing each other in the parts.

Finally, an example process of the interconnect structural limit decision 19 based on the frequency 12 will be described. An interconnect structure having an electrical characteristic required for signal propagation is obtained using the frequency 12 of a signal propagating through the first circuit board as signal request information 14, by

Si=Gi(f) (2)

where Si (i=0, 1, 2, 3, . . . , k, . . . , and n) is an interconnect structure, f is the frequency of a propagating signal, and Gi (i=0, 1, 2, 3, . . . , k, . . . , and n) is a function which calculates the interconnect structure from the frequency f. The function Gi is preferably selected based on the corresponding interconnect structure Si. For example, when the interconnect structure S1 is an interconnect length, the function G1 is selected, when the interconnect structure S2 is an interconnect length and an interconnect width, the function G2 is selected, etc. Using the frequency 12 as input information, the function G1 calculates an interconnect length as an interconnect structural limit which is a condition required in the interconnect structural limit decision 19. The interconnect length which allows propagation of a signal having the frequency 12 is referred to as a structural limit 20.

Note that, instead of the frequency 12 as the signal request information 14, the rise or fall time of a signal propagating through the first circuit board may be used as the signal request information 14.

### Second Embodiment

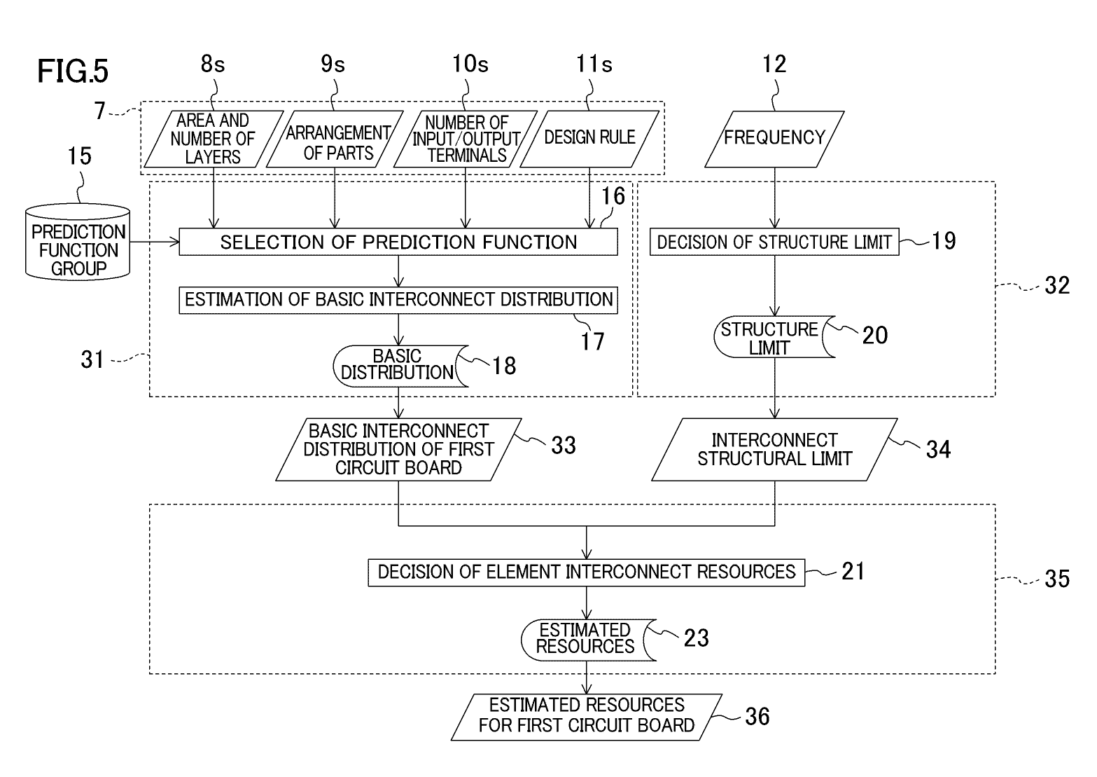

In FIG. 5 showing a second embodiment, circuit board information 7 including design information 8s, 9s, 10s, and 11s for a first circuit board is input information, and a basic distribution estimation process 31 is performed to output a first circuit board basic interconnect distribution 33. The first circuit board basic interconnect distribution 33 is a distribution (basic distribution 18) of the number of interconnects with respect to an interconnect length of the first circuit board (e.g., expression (1)). The basic distribution estimation process 31 includes a prediction function selection 16, a basic interconnect distribution estimation 17 based on a prediction function for the first circuit board, and the basic distribution 18. As in FIG. 3, a prediction function is selected from a prediction function group 15 in the prediction function selection 16.

A structure process 32 of deciding an interconnect structure which provides a satisfactory electrical characteristic based on the frequency 12 as input information, outputs an interconnect structural limit 34. The interconnect structural limit 34 includes information about an interconnect structure which allows propagation of a signal having the frequency 12. As in FIG. 3, the structure process 32 includes interconnect structural limit decision 19 and a structural limit 20.

A resource estimation process 35 is performed using the first circuit board basic interconnect distribution 33 and the interconnect structural limit 34 as input information, to output estimated resources 36 for the first circuit board. As in FIG. 3, the resource estimation process 35 includes element interconnection resource decision 21 within a limit of the first circuit board and estimated resources 23. The element interconnection resource decision 21 within the limit of the first circuit board decides element interconnection resources which are an interconnect distribution which is obtained by extracting interconnects falling within the interconnect structural limit 34 in the basic distribution of interconnects in the first circuit board basic interconnect distribution 33. Information including the element interconnection resources as the estimated resources 23 is output to the estimated resources 36 for the first circuit board.

### Third Embodiment

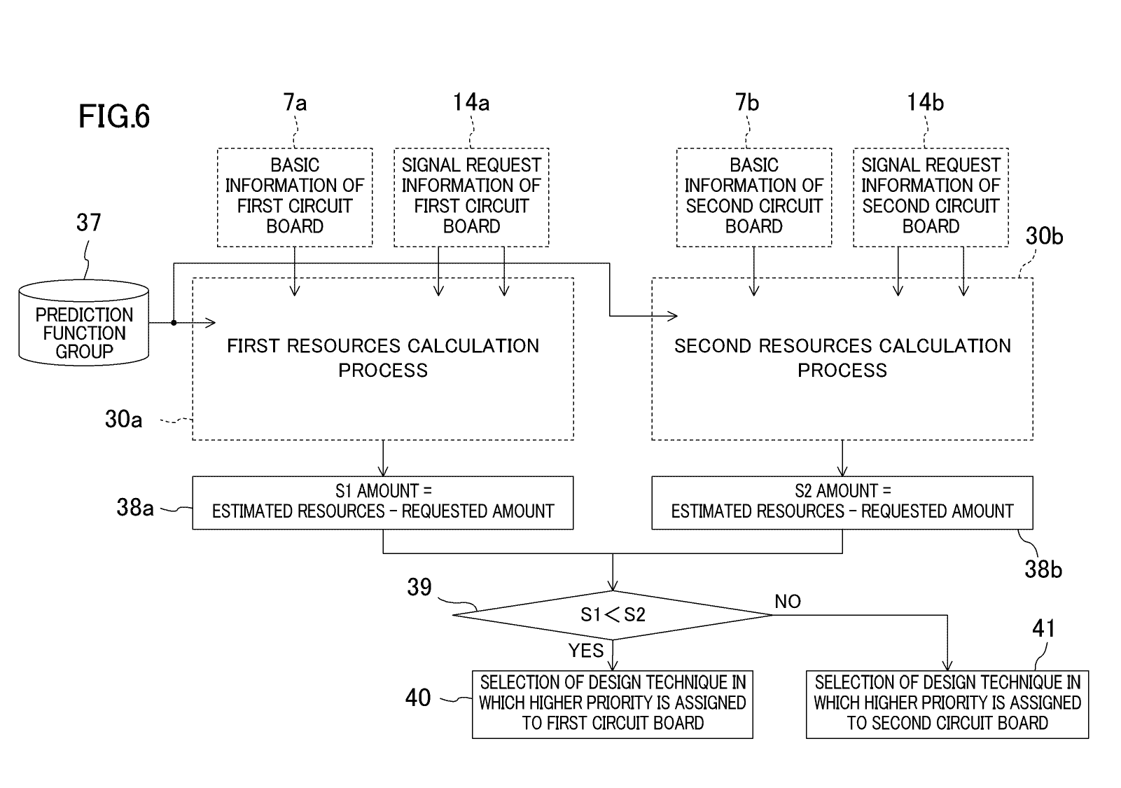

In FIG. 6 showing a third embodiment, input are circuit board information 7a including design information corresponding to design information 8s, 9s, 10s, and 11s for a first circuit board, signal request information 14a for the first circuit board corresponding to the signal request information 14 of FIG. 3, circuit board information 7b including design information corresponding to design information 8s, 9s, 10s, and 11s for a second circuit board, and signal request information 14b for the second circuit board corresponding to the signal request information 14 of FIG. 3.

There are two resource calculation processes: a first resource calculation process 30a to which the circuit board information 7a for the first circuit board and the signal request information 14a are input; and a second resource calculation process 30b to which the circuit board information 7b for the second circuit board and the signal request information 14b are input. In the first resource calculation process 30a, the circuit board information 7a and the signal request information 14a are input, and a prediction function group 37 is used to output an S1 amount 38a (=estimated resources−requested amount). Here, the estimated resources correspond to the estimated resources 23 of FIG. 3, and the requested amount corresponds to the requested amount 24 of FIG. 3. In the second resource calculation process 30b, the circuit board information 7b and the signal request information 14b are input, and the prediction function group 37 is used to output an S2 amount 38b (=estimated resources−requested amount). Here, the estimated resources correspond to the estimated resources 23 of FIG. 3, and the requested amount corresponds to the requested amount 24 of FIG. 3. The prediction function group 37 corresponds to the prediction function group 15 of FIG. 3. However, the first and second circuit boards typically have significantly different shapes, and therefore, prediction functions suitable for the first and second circuit boards are prepared, FIG. 3, so that a larger number of functions than the prediction function group 15 are provided.

The S1 amount 38a is compared with the S2 amount 38b (comparison 39). When the S2 amount 38b is larger than the S1 amount 38a, a design technique in which a higher priority is assigned to the first circuit board is selected (selection 40). On the other hand, when the S2 amount 38b is smaller than the S1 amount 38a, a design technique in which a higher priority is assigned to the second circuit board is selected (selection 41). Based on the result of the selection 40 or 41, as shown in FIG. 2 interconnects from the LSI 3 to the PKG 2, interconnects from the PCB 1 to the PKG 4, and interconnects from the PKG 4 to the LSI 5 can be provided without crossing each other in the parts.

As described above, the electronic system design method of the present disclosure can decide priority levels of designing of interconnection for LSIs, PKGs, and PCBs, and is useful for design tools etc. for reducing design time.

What is claimed is:

1. A method for designing an electronic system comprising the steps of:
calculating a basic interconnect distribution for a first circuit board based on a prediction function configured to predict an interconnect distribution for a circuit board using design information for the first circuit board as input data; and
outputting the basic interconnect distribution.

2. The method of claim 1, wherein
the design information is the area of the first circuit board.

3. The method of claim 1, wherein
the design information is the number of layers of the first circuit board.

4. The method of claim 1, wherein
the design information is the locations of parts to be provided on the first circuit board.

5. The method of claim 1, wherein
the design information is the number of input or output terminals of parts to be provided on the first circuit board.

6. The method of claim 1, wherein
the design information is a design rule for the first circuit board.

7. A method for designing an electronic system comprising the steps of:
calculating element interconnection resources within a structural limit of a first circuit board using, as input information, an interconnect distribution for the first circuit board and a structural limit of interconnects based on an electrical characteristic; and
outputting the element interconnection resources.

8. The method of claim 7, wherein
the electrical characteristic is a frequency of a signal propagating through the interconnects of the first circuit board.

9. The method of claim 7, wherein
the electrical characteristic is the rise or fall time of a signal propagating through the interconnects of the first circuit board.

10. A method for designing an electronic system comprising the steps of:
calculating a basic interconnect distribution for a first circuit board based on a prediction function configured to predict an interconnect distribution for a circuit board using design information for the first circuit board as first input data;
calculating, as element interconnection resources, the basic interconnect distribution within a structural limit based on an electrical characteristic; and
outputting a result of comparing the element interconnection resources with the number of requests for a signal requiring the electrical characteristic.

11. The method of claim 10, wherein
the comparison result is an interconnection design technique for the first circuit board.

12. A method for designing an electronic system comprising the steps of:
calculating a first interconnect distribution for a first circuit board based on a prediction function configured to predict an interconnect distribution for a circuit board using design information for the first circuit board as first input data, calculating, as first element interconnect resources, the basic interconnect distribution within a structural limit based on an electrical characteristic, and outputting a first result of comparing the element interconnection resources with the number of requests for a signal requiring the electrical characteristics;
calculating a second interconnect distribution for a second circuit board based on a prediction function configured to predict an interconnect distribution for a circuit board using design information for the second circuit board as second input data, calculating, as second element interconnect resources, the basic interconnect distribution within a structural limit based on an electrical characteristic, and outputting a second result of comparing the element interconnection resources with the number of requests for a signal requiring the electrical characteristics; and
outputting an analysis result of comparing the first comparison result with the second comparison result.

13. The method of claim 12, wherein
based on the analysis result, a result of determining which of the first and second circuit boards is designed with a higher priority, is output.

14. An electronic device comprising:
a semiconductor chip;
a first package;
a plurality of connectors configured to connect the semiconductor chip and the first package; and
a plurality of interconnects configured to connect to a plurality of external connectors of the first package,
wherein
the plurality of connectors are a group of signals, and
the plurality of interconnect do not cross each other.

15. The electronic device of claim 14, wherein
a plurality of first connection terminals of a circuit board are each connected to a corresponding one of the plurality of external connectors, and
interconnects of the substrate connected to a plurality of second connection terminals of the circuit board connected to a plurality of external connectors of a second package, are the group of signals, and do not cross each other.

16. The electronic device of claim 14, wherein
a circuit board on which the semiconductor chip and the first package are mounted provides a power supply plane dedicated to the group of signals.
